(19) United States
(12) Patent Application Publication
(10) Pub. No.: US 2025/0358959 A1
(43) Pub. Date: Nov. 20, 2025

(54) COOLING MECHANISM AND COMPUTING DEVICE

(71) Applicants: SQ TECHNOLOGY (SHANGHAI) CORPORATION, Shanghai (CN); INVENTEC CORPORATION, Taipei (TW)

(72) Inventors: Kangguang Zhu, Shanghai (CN); Hong-Chou Lin, Taipei (TW); Yu-Fan Chen, Taipei (TW)

(21) Appl. No.: 18/748,139

(22) Filed: Jun. 20, 2024

(30) Foreign Application Priority Data
May 15, 2024 (CN) 202410607219.1

(51) Int. Cl. H05K 7/20; G06F 1/20

(52) U.S. Cl. CPC H05K 7/20272; G06F 1/20

(57) ABSTRACT

A cooling mechanism and a computing device are provided. The cooling mechanism includes a liquid cooling assembly including a water separator, a water outlet pipe, and a liquid cooling plate connected to the water separator through the water outlet pipe, and the water separator being configured to accommodate a coolant; and a liquid inlet detection assembly provided on the water separator and being configured to detect an inflow temperature of the coolant flowing into the water separator.

### CROSS-REFERENCE TO RELATED APPLICATIONS

This application claims priority of Chinese Patent Application No. 2024106072191, filed on May 15, 2024, entitled “COOLING MECHANISM AND COMPUTING DEVICE”, the entire content of which is incorporated herein in its entirety.

### TECHNICAL FIELD

The present disclosure relates to computing devices, and in particular to a cooling mechanism and a computing device.

### BACKGROUND

With the development of technologies such as the Internet of Things and 5G, the speed and scale of data generation continue to expand, and the need to process and analyze data in real time is becoming more and more urgent. In the era of new data centers, cloud computing and edge computing are cooperated to form a distributed computing system, which can effectively improve data processing speed and reduce network latency. As such, edge computing devices need to have higher computing power and lower power consumption to adapt to large-scale distributed deployment. Therefore, high-efficiency and energy-saving liquid cooling technology emerges, and gradually becomes a key way to solve the energy efficiency problem of new data centers.

Currently, a cooling mechanism of full immersion liquid cooling is the trend in the market. The cooling mechanism can better monitor a temperature of coolant in a liquid cooling mechanism by providing a temperature sensor. However, the temperature sensor is usually directly mounted on the liquid cooling mechanism. The assembly of the temperature sensor has complicated steps, and a mounting position of the temperature sensor is prone to water leakage, which has the defects of inconvenient assembly and poor stability.

### SUMMARY

Accordingly, a cooling mechanism and a computing device are provided.

According to a first aspect, a cooling mechanism includes a liquid cooling assembly including a water separator, a water outlet pipe, and a liquid cooling plate connected to the water separator through the water outlet pipe, and the water separator being configured to accommodate a coolant; and a liquid inlet detection assembly provided on the water separator and configured to detect an inflow temperature of the coolant flowing into the water separator.

In one of the embodiments, the water separator is provided with an accommodating cavity and a detection hole in communication with the accommodating cavity, and the liquid inlet detection assembly is accommodated in the detection hole.

In one of the embodiments, the liquid inlet detection assembly includes a connection column and a temperature sensor, the water separator is provided with a connection portion at an end thereof connected to the connection column, the connection column is provided with a connection channel extending axially therethrough, the temperature sensor includes a detection head and a data transmission line, the detection head is provided at an end of the connection portion, and the data transmission line extends through the connection channel and is connected to the detection head.

In one of the embodiments, the cooling mechanism further includes waterproof glue filling a gap between an inner wall of the connecting channel and the data transmission line.

In one of the embodiments, the liquid inlet detection assembly further includes a sealing ring, the connection column further includes a mounting portion connected to an end of the connection portion away from the water separator, the sealing ring is sleeved on the connection portion, one side of the sealing ring abuts against an end surface of the mounting portion, and another side of the sealing ring abuts against the water separator.

In one of the embodiments, an outer side wall of the connection portion is provided with an external thread, an inner wall of the detection hole is provided with an internal thread, and the external thread is engaged with the internal thread.

In one of the embodiments, the water separator includes a quick-release connecting member located at the detection hole, and the connection portion is detachably connected to the quick-release connecting member.

In one of the embodiments, a cross-section of the mounting portion perpendicular to an axis thereof is hexagonal.

In one of the embodiments, the water separator is further provided with a plurality of water outlets that are in communication with the accommodating cavity, a plurality of water outlet pipes are provided and are connected to the plurality of water outlets in a one-to-one correspondence.

According to a second aspect, a computing device is provided including any one of the aforementioned cooling mechanisms.

In one of the embodiments, the computing device further includes a computer case, a computing mechanism, an adapter plate, and a motherboard. The computing mechanism, the adapter plate, the motherboard, and the cooling mechanism are accommodated in the computer case, the water separator is provided with an accommodating cavity, the computer case is provided with a liquid inlet pipe and a liquid outlet pipe, the liquid inlet pipe is in communication with the accommodating cavity, the liquid cooling plate of the liquid cooling assembly is provided on the computing mechanism, the adapter plate is provided on the motherboard and is electrically connected to the liquid inlet detection assembly, motherboard comprises a baseboard management controller configured to acquire a detection signal from the liquid inlet detection assembly.

In one of the embodiments, the computing device further includes a liquid outlet detection assembly provided at a port of the liquid outlet pipe in the chassis, the liquid outlet detection assembly is configured to detect an outflow temperature of the coolant and is electrically connected to the adapter plate, and the baseboard management controller is further configured to acquire a detection signal from the liquid outlet detection assembly.

According to the aforementioned cooling mechanism and the aforementioned computing device, the coolant is delivered into the water separator, and the water separator delivers the coolant to the liquid cooling plate through the water outlet pipe. The liquid cooling plate is mounted on a component that needs to be cooled, and the coolant removes heat through the liquid cooling plate, so as to dissipate heat from the component on which the liquid cooling plate is mounted. By mounting the liquid inlet detection assembly to the water separator, the temperature of the coolant in the water separator can be detected, so as to detect an inflow temperature of the coolant. The structure of the liquid inlet detection assembly can be designed according to the mounting requirements, so that the liquid inlet detection assembly can be conveniently and quickly mounted to the water separator, and the specially designed structure has good waterproof performance to avoid water leakage, and is convenient to mounting and has good stability.

The details of one or more embodiments of the present disclosure are set forth in the accompanying drawings and the description below. Other features, objects and advantages of the present disclosure will become apparent from the description, the accompanying drawings, and the claims.

### BRIEF DESCRIPTION OF THE DRAWINGS

To illustrate the technical solutions according to the embodiments of the present invention or in the prior art more clearly, the accompanying drawings for describing the embodiments or the prior art are introduced briefly in the following. Apparently, the accompanying drawings in the following description are only some embodiments of the present invention, and persons of ordinary skill in the art can derive other drawings from the accompanying drawings without creative efforts.

FIG. 1 is a perspective view of a cooling mechanism according to an embodiment of the present disclosure.

FIG. 2 is a perspective view of a liquid inlet detection assembly of FIG. 1.

FIG. 3 is a cross-sectional view of the liquid inlet detection assembly of FIG. 2.

FIG. 4 is a perspective view showing the liquid inlet detection assembly mounted to a water separator.

FIG. 5 is a perspective view of the water separator according to an embodiment of the present disclosure.

FIG. 6 is a perspective view of a computing device according to an embodiment of the present disclosure.

Reference signs:
10. Computer case; 11. Liquid inlet pipe; 12. Liquid outlet pipe; 20. Computing mechanism; 30. Cooling mechanism; 40. Adapter plate; 50. Motherboard; 60. Liquid outlet detection assembly;
100. Liquid cooling assembly; 110. Water separator; 100A. accommodating cavity; 111. Detection hole; 112. Water outlet; 120. Water outlet pipe; 130. Liquid cooling plate;
200. Liquid inlet detection assembly; 210. Connection column; 210A. Connection channel; 211. Connection portion; 212. Mounting portion; 220. Temperature sensor; 221. Probe; 222. Data transmission line; 230. Sealing ring; 240. Waterproof glue.

### DETAILED DESCRIPTION OF THE EMBODIMENTS

In order to make the above objects, features and advantages of the present disclosure clear and easier to understand, the specific embodiments of the present disclosure are described in detail below in combination with the accompanying drawings. Many specific details are set forth in the following description to facilitate a full understanding of the present disclosure. However, the present disclosure can be implemented in many ways different from those described herein, and those skilled in the art can make similar improvements without departing from the connotation of the present disclosure. Therefore, the present disclosure is not limited by the specific embodiments disclosed below.

In the description of the present disclosure, it should be understood that the terms “center”, “longitudinal”, “transverse”, “length”, “width”, “thickness”, “upper”, “lower”, “front”, “rear”, “left”, “right”, “vertical”, “horizontal”, “top”, “bottom”, “inner”, “outer”, “clockwise”, “counterclockwise”, “axial”, “radial”, “circumferential direction” are based on the azimuth or position relationship shown in the attached drawings, which are only for the convenience of describing the present disclosure and simplifying the description, rather than indicating or implying that the device or element must have a specific azimuth, be constructed and operated in a specific azimuth, so such terms cannot be understood as a limitation of the present disclosure.

In addition, the terms “first” and “second” are only used for descriptive purposes and cannot be understood as indicating or implying relative importance or implicitly indicating the number of indicated technical features. Thus, the features defined with “first” and “second” may explicitly or implicitly include at least one of the features. In the description of the present disclosure, “a plurality of” means at least two, such as two, three, etc., unless otherwise expressly and specifically defined.

In the present disclosure, unless otherwise expressly specified and limited, the terms “mount”, “connect”, “contact”, “fix” and other terms should be understood in a broad sense, for example, they can be fixed connections, detachable connections, or integrated. They can be mechanical connection or electrical connection. They can be directly connected or indirectly connected through an intermediate medium. They can be the connection within two elements or the interaction relationship between two elements, unless otherwise expressly limited. For those skilled in the art, the specific meaning of the above terms in the present disclosure can be understood according to the specific situation.

In the present disclosure, unless otherwise expressly specified and limited, the first feature “above” or “below” the second feature may be in direct contact with the first and second features, or the first and second features may be in indirect contact through an intermediate medium. Moreover, the first feature is “above” the second feature, but the first feature is directly above or diagonally above the second feature, or it only means that the horizontal height of the first feature is higher than the second feature. The first feature is “below” of the second feature, which can mean that the first feature is directly below or obliquely below the second feature, or simply that the horizontal height of the first feature is less than that of the second feature.

It should be noted that when an element is called “fixed to” or “provided on” another element, it can be directly on another element or there can be a centered element. When an element is considered to be “connected” to another element, it can be directly connected to another element or there may be intermediate elements at the same time. The terms “vertical”, “horizontal”, “up”, “down”, “left”, “right” and similar expressions used herein are for the purpose of illustration only and do not represent the only embodiment.

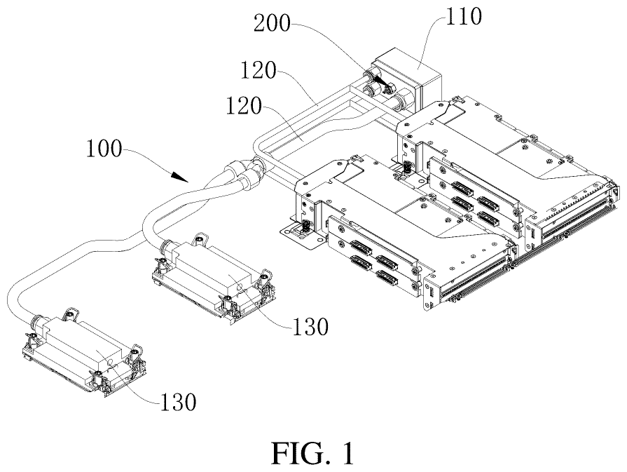

Referring to FIG. 1, which is a perspective view of a cooling mechanism according to an embodiment of the present disclosure. The cooling mechanism includes a liquid cooling assembly 100 and a liquid inlet detection assembly 200. The liquid cooling assembly 100 includes a water separator 110, a water outlet pipe 120, and a liquid cooling plate 130 connected to the water separator 110 through the water outlet pipe 120. The water separator 110 and the water outlet pipe 120 are configured to accommodate coolant. The liquid inlet detection assembly 200 is provided on the water separator 110 and is configured to detect an inflow temperature of the coolant flowing into the water separator 110. Specifically, the cooling mechanism can deliver the coolant into the water separator 110 through a water pump connected to an external pipeline.

According to the aforementioned cooling mechanism, the coolant is delivered into the water separator 110, and the water separator 110 delivers the coolant to the liquid cooling plate 130 through the water outlet pipe 120. The liquid cooling plate 130 is mounted to a component that needs to be cooled, and the coolant dissipates heat when flowing in the liquid cooling plate 130, so as to dissipate heat from the component on which the liquid cooling plate 130 is mounted. By mounting the liquid inlet detection assembly 200 on the water separator 110, the temperature of the coolant in the water separator 110 can be detected, so as to detect the inflow temperature of the coolant.

According to the aforementioned cooling mechanism, the structure of the liquid inlet detection assembly 200 can be designed according to the mounting requirements, so that the liquid inlet detection assembly 200 can be conveniently and quickly mounted to the water separator 110, and the specially designed structure has good waterproof performance to avoid water leakage, and is convenient to mounting and has good stability.

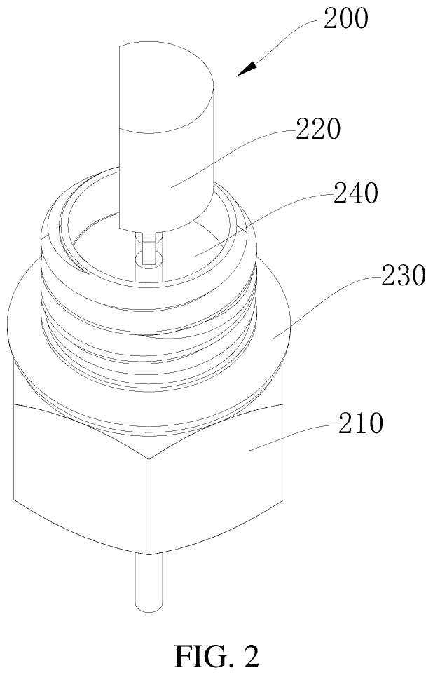

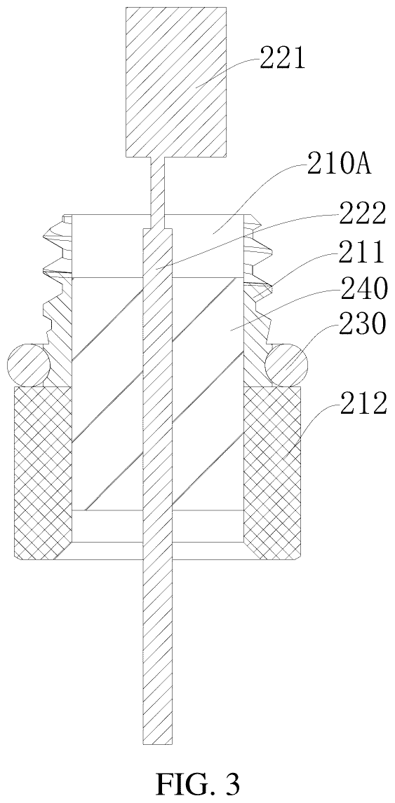

Referring to FIG. 2 and FIG. 3, in some embodiments, the liquid inlet detection assembly 200 includes a connection column 210 and a temperature sensor 220. The water separator 110 is provided with a connection portion 211 at an end thereof, which is connected to the connection column 210. The connection column 210 is provided with a connection channel 210A extending axially therethrough. The temperature sensor 220 includes a detection head 221 and a data transmission line 222, the detection head 221 is provided at an end of the connection portion 211, and the data transmission line 222 extends through the connection channel 210A and is connected to the detection head 221. The connection portion 211 is provided at the end of the liquid inlet detection assembly 200 connected to the water separator 110, so that the connection portion 211 and the water separator 110 form a convenient mounting structure, thereby saving the mounting steps of the temperature sensor 220 and improving the mounting efficiency. The detection head 221 of the temperature sensor 220 is provided in the water separator 110 through the connection channel 210A to detect the temperature of the coolant in the water separator 110, and then the temperature data is transmitted through the data transmission line 222, thereby achieving stably monitoring of the temperature of the coolant.

Further, referring to FIG. 2 and FIG. 3, the cooling mechanism further includes a waterproof glue 240 filling a gap between an inner wall of the connection channel 210A and the data transmission line 222. In order to prevent the coolant from leaking from the connection channel 210A, after the temperature sensor 220 is mounted to the connection column 210, the connection channel 210A is filled with the waterproof glue 240, so that the whole liquid inlet detection assembly 200 is waterproof, the leakage is avoided, and the reliability and stability of the liquid inlet detection assembly 200 are improved.

Further, referring to FIG. 2 and FIG. 3, the liquid inlet detection assembly 200 further includes a sealing ring 230. The connection column 210 further includes a mounting portion 212 connected to an end of the connection portion 211 away from the water separator 110. The sealing ring 230 is sleeved on the connection portion 211, one side of the sealing ring 230 abuts against an end surface of the mounting portion 212, and the other side of the sealing ring 230 abuts against the water separator 110. Since the sealing ring 230 is sleeved on the connection portion 211, when the connection column 210 is mounted to the water separator 110, a gap between the mounting portion 212 and the water separator 110 is filled by the sealing ring 230, so that the overall waterproof performance of the connection column 210 is enhanced, water leakage is avoided, and the reliability and stability of the liquid inlet detection assembly 200 are improved.

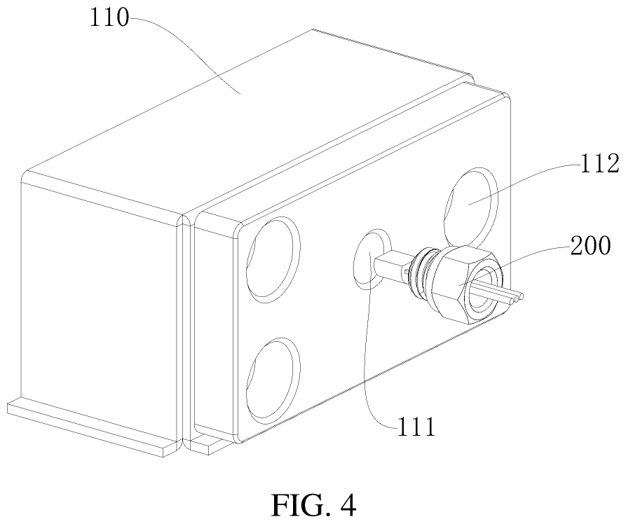

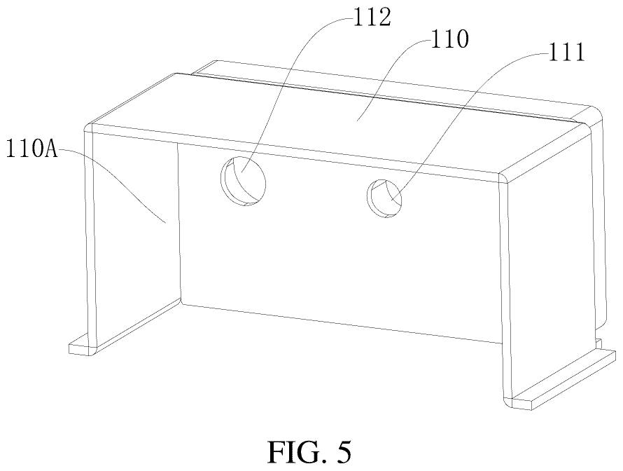

In an embodiment, referring to FIG. 4 and FIG. 5, the water separator 110 is provided with an accommodating cavity 100A and a detection hole 111 in communication with the accommodating cavity 100A. The liquid inlet detection assembly 200 is accommodated in the detection hole 111. The water separator 110 is provided with the accommodating cavity 100A, and the coolant is stored in the accommodating cavity 100A. The detection hole 111 is in communication with the accommodating cavity 100A, so that the detection head 221 of the liquid inlet detection assembly 200 is in contact with the coolant and detects the temperature of the coolant in the accommodating cavity 100A.

In an embodiment, referring to FIG. 2 to FIG. 4, an outer side wall of the connection portion 211 is provided with an external thread, an inner wall of the detection hole 111 is provided with an internal thread, and the external thread is engaged with the internal thread. The connection portion 211 is threadedly engaged in the detection hole 111, so that the mounting method is more convenient. Moreover, the thread has a good sealing connection effect, which can further enhance the waterproof ability of the liquid inlet detection assembly 200, and is convenient to mounting and not prone to water leakage. In other embodiments, the water separator 110 includes a quick-release connecting member located in the detection hole 111, and the connection portion 211 is detachably connected to the quick-release connection member. By providing the quick-release connection member, the connection portion 211 can be quickly connected to the water separator 110 to facilitate mounting.

In an embodiment, referring to FIG. 2, a cross-section of the mounting portion 212 perpendicular to an axis thereof is hexagonal, such that the mounting portion 212 can be engaged in the detection hole 111 by a tool such as a wrench, and the liquid inlet detection assembly 200 can be quickly mounted by the wrench, thereby improving the mounting efficiency of the liquid inlet detection assembly 200.

In an embodiment, referring to FIG. 4 and FIG. 5, the water separator 110 is further provided with a plurality of water outlets 112 that are in communication with the accommodating cavity 110A, and a plurality of water outlet pipes 120 are provided and are connected to the plurality of water outlets 112 in a one-to-one correspondence. When the cooling mechanism needs to dissipate heat from a plurality of components, the plurality of water outlet pipes 120 may be provided to dissipate heat from different components, respectively. The water separator 110 is provided with the plurality of water outlets 112, so that the coolant is delivered to a plurality of liquid cooling plates 130 through the plurality of water outlet pipes 120, thereby improving the cooling efficiency of the cooling mechanism.

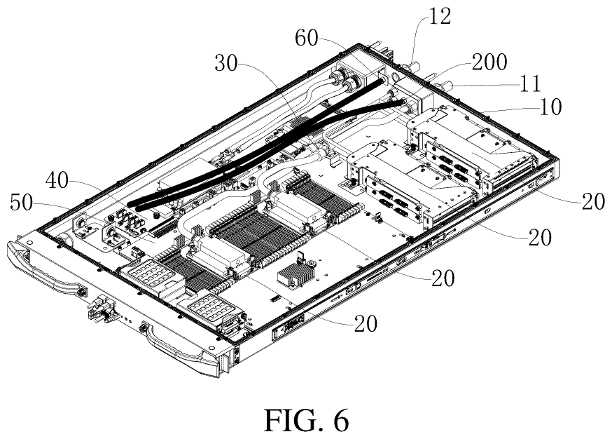

In one embodiment, referring to FIG. 6, a computing device is further provided, which includes a computer case 10, a computing mechanism 20, an adapter plate 40, a motherboard 50, and a cooling mechanism 30 according to any one of the above embodiments. The computing mechanism 20, the adapter plate 40, the motherboard 50, and the cooling mechanism 30 are accommodate in the computer case 10. The computer case 10 is provided with a liquid inlet pipe 11 in communication with the accommodating cavity 110A of the cooling mechanism 30 and a liquid outlet pipe 12. The liquid cooling plate 130 of the cooling mechanism 30 is provided on the computing mechanism 20. The adapter plate 40 is provided on the motherboard 50 and electrically connected to the liquid inlet detection assembly 200. The motherboard 50 is provided with a baseboard management controller (BMC) configured to acquire a detection signal from the liquid inlet detection assembly 200.

Specifically, in this embodiment, the baseboard management controller is configured to read detection values from the liquid inlet detection assembly 200 and output the detection values to a terminal. The baseboard management controller reads the detection values once per second. Moreover, the baseboard management controller compares the detection values with preset values, respectively. If the detection value is greater than the corresponding preset value, a warning sign will be displayed on a display of the terminal to warn a staff to check and improve the security of the computing device.

Specifically, the computing mechanism 20 includes a plurality of CPUs and a plurality of GPUs, and each CPU and each GPU are provided with the liquid cooling plates 130, respectively. The water separator 110 diverts the coolant to the liquid cooling plate 130 of each CPU through one of the water outlet pipes 120. The liquid cooling plate 130 covers the CPUs for cooling, and then the coolant is discharged from the liquid cooling plate 130 into the computer case 10. The coolant is also diverted into the liquid cooling plate 130 of each GPU through the other two water outlet pipes 120. The liquid cooling plate 130 is provided in the GPU to cools the GPU, and then the coolant flows from the liquid cooling plate 130 into the GPU, and then is discharged into the computer case 10.

According to the computing device of this embodiment, the external pipeline delivers the coolant to the cooling mechanism 30 through the liquid inlet pipe 11, and the water separator 110 of the cooling mechanism 30 cools the computing mechanism 20 through the water outlet pipe 120 and the liquid cooling plate 130. After flowing through the liquid cooling plate 130, the coolant is directly delivered into the computer case 10, and then the coolant is discharged from the computer case 10 through the liquid outlet pipe 12. The liquid inlet detection assembly located on the water separator 110 can detect the inflow temperature of the coolant, and then transmit a detected inflow temperature data to the adapter plate 40, and the adapter plate 40 transmits the data to the baseboard management controller for processing.

Specifically, during the assembly process of the cooling mechanism 30, the liquid inlet detection assembly 200 can be mounted quickly and conveniently, and the liquid inlet detection assembly 200 has good waterproof performance and improves the stability of operation by providing the waterproof glue 240 and the sealing ring 230.

In an embodiment, referring to FIG. 6, the computing device further includes a liquid outlet detection assembly 60 provided at a port of the liquid outlet pipe 12 in the computer case 10. The liquid outlet detection assembly 60 is electrically connected to the adapter plate 40 and is configured to detect an outflow temperature of the coolant. The baseboard management controller is further configured to acquire a detection signal from the liquid outlet detection assembly 60. In order to monitor the outflow temperature of the coolant from the computer case 10, the liquid outlet detection assembly 60 is provided at the port of the liquid outlet port 12 in the computer case 10, an outflow temperature data of the coolant detected by the liquid outlet detection assembly 60 is transmitted to the adapter plate 40, and the adapter plate 40 transmits the data to the baseboard management controller for processing, so that the inflow temperature and the outflow temperature of the coolant can be monitored in real time.

The aforementioned cooling mechanism and the aforementioned computing device described have the following beneficial effects:
1. The liquid inlet detection assembly 200 can be designed according to the installation requirements. The liquid inlet detection assembly 200 can be conveniently and quickly mounted to the water separator 110 through the threaded structure, and the specially designed structure has good waterproof performance to avoid water leakage, and is convenient to mounting and has good stability.
2. In order to prevent the coolant from leaking from the connection channel 210A, after the temperature sensor 220 is mounted to the connection column 210, the connection channel 210A is filled with the waterproof glue 240, so that the whole liquid inlet detection assembly 200 is waterproof, the leakage is avoided, and the reliability and stability of the liquid inlet detection assembly 200 are improved.
3. The sealing ring 230 is sleeved on the connection portion 211, when the connection column 210 is mounted to the water separator 110, the gap between the mounting portion 212 and the water separator 110 is filled by the sealing ring 230, so that the overall waterproof performance of the connection column 210 is enhanced, water leakage is avoided, and the reliability and stability of the liquid inlet detection assembly 200 are improved.

The above-mentioned embodiments do not constitute a limitation on the protection scope of the technical solution. Any modifications, equivalent replacements and improvements made within the spirit and principles of the above-mentioned embodiments shall be included within the protection scope of this technical solution.

The foregoing descriptions are merely specific embodiments of the present disclosure, but are not intended to limit the protection scope of the present disclosure. Any variation or replacement readily figured out by a person skilled in the art within the technical scope disclosed in the present disclosure shall all fall within the protection scope of the present disclosure.

What is claimed is:

1. A cooling mechanism, comprising:
a liquid cooling assembly comprising a water separator, a water outlet pipe, and a liquid cooling plate connected to the water separator through the water outlet pipe, and the water separator being configured to accommodate a coolant; and
a liquid inlet detection assembly provided on the water separator and configured to detect an inflow temperature of the coolant flowing into the water separator.

2. The cooling mechanism according to claim 1, wherein the water separator is provided with an accommodating cavity and a detection hole in communication with the accommodating cavity, and the liquid inlet detection assembly is accommodated in the detection hole.

3. The cooling mechanism according to claim 2, wherein the liquid inlet detection assembly comprises a connection column and a temperature sensor, the water separator is provided with a connection portion at an end thereof connected to the connection column, the connection column is provided with a connection channel extending axially therethrough, the temperature sensor comprises a detection head and a data transmission line, the detection head is provided at an end of the connection portion, and the data transmission line extends through the connection channel and is connected to the detection head.

4. The cooling mechanism according to claim 3, further comprising waterproof glue filling a gap between an inner wall of the connecting channel and the data transmission line.

5. The cooling mechanism according to claim 3, wherein the liquid inlet detection assembly further comprises a sealing ring, the connection column further comprises a mounting portion connected to an end of the connection portion away from the water separator, the sealing ring is sleeved on the connection portion, one side of the sealing ring abuts against an end surface of the mounting portion, and another side of the sealing ring abuts against the water separator.

6. The cooling mechanism according to claim 3, wherein an outer side wall of the connection portion is provided with an external thread, an inner wall of the detection hole is provided with an internal thread, and the external thread is engaged with the internal thread.

7. The cooling mechanism according to claim 3, wherein the water separator comprises a quick-release connecting member located at the detection hole, and the connection portion is detachably connected to the quick-release connecting member.

8. The cooling mechanism according to claim 5, wherein a cross-section of the mounting portion perpendicular to an axis thereof is hexagonal.

9. The cooling mechanism according to claim 3, wherein the water separator is further provided with a plurality of water outlets that are in communication with the accommodating cavity, a plurality of water outlet pipes are provided and are connected to the plurality of water outlets in a one-to-one correspondence.

10. A computing device, comprising the cooling mechanism according to claim 1.

11. The computing device according to claim 10, further comprising a computer case, a computing mechanism, an adapter plate, and a motherboard, wherein the computing mechanism, the adapter plate, the motherboard, and the cooling mechanism are accommodated in the computer case, the water separator is provided with an accommodating cavity, the computer case is provided with a liquid inlet pipe and a liquid outlet pipe, the liquid inlet pipe is in communication with the accommodating cavity, the liquid cooling plate of the liquid cooling assembly is provided on the computing mechanism, the adapter plate is provided on the motherboard and is electrically connected to the liquid inlet detection assembly, the motherboard comprises a baseboard management controller configured to acquire a detection signal from the liquid inlet detection assembly.

12. The computing device according to claim 11, further comprising a liquid outlet detection assembly provided at a port of the liquid outlet pipe in the computer case, wherein the liquid outlet detection assembly is configured to detect an outflow temperature of the coolant and is electrically connected to the adapter plate, and the baseboard management controller is further configured to acquire a detection signal from the liquid outlet detection assembly.
